(19) United States
(12) Patent Application Publication
(10) Pub. No.: US 2019/0179069 A1
(43) Pub. Date: Jun. 13, 2019

(54) METHOD OF PREPARING FUNCTIONAL FILM

(71) Applicant: Wuhan China Star Optoelectronics Semiconductor Display Technology Co., Ltd., Wuhan, Hubei (CN)

(72) Inventor: Chunmei HE, Wuhan, Hubei (CN)

(21) Appl. No.: 15/749,283

(22) PCT Filed: Jan. 4, 2018
(86) PCT No.: PCT/CN2018/071261

§ 371 Date: Jan. 31, 2018

(30) Foreign Application Priority Data
Dec. 12, 2017 (CN) 201711316221.X

(51) Int. Cl. G02B 5/30; G09F 9/30; H01L 27/32; H01L 51/52; H01L 51/00

(52) U.S. Cl. CPC G02B 5/3033; G09F 9/301; H01L 27/323; H01L 2251/5338; H01L 51/5253; H01L 51/0097; H01L 27/3232

(57) ABSTRACT

A method of preparing functional film is provided. The method of preparing functional film, the functional film used for a flexible display panel, comprising forming a linear polarizer and a phase difference film by coating liquid crystal on a first side of a substrate, the linear polarizer is located between the substrate and the phase difference film, or the phase difference film is located between the substrate and the linear polarizer; forming a touch electrode layer on the first side or a second side of the substrate. The invention could reduce thickness of the flexible display panel, enhance curving property of the flexible display panel such that easily curving or banding the flexible display panel.

### RELATED APPLICATIONS

The present application is a National Phase of International Application Number PCT/CN2018/071261, filed Jan. 4, 2018, and claims the priority of China Application No. 201711316221.X, filed Dec. 12, 2017.

### FIELD OF THE DISCLOSURE

The disclosure relates to a display technical field, and more particularly to a method of preparing functional film.

### BACKGROUND

Flexible OLED (organic light emitting diode) has number of advantageous such as thin, light, not fragile, bendable and wearable, and get more focus thereon. For example the flexible AMOLED (Active-matrix organic light emitting diode) display panel.

The currently flexible OLED display panel includes a polarizer. The polarizer is made by TAC (Triacetyl Cellulose) layer, a PVA (polyvinyl alcohol) layer, a phase difference film, wherein the most thin of the currently PVA is 5 um so that thickness of the polarizer is over 5 um. These layers need to bind together by adhesive, and the adhesive is also will increase thickness of polarizer. Secondary, the currently flexible OLED touch display panel further comprises a touch electrode layer, a polarizer and a touch electrode layer, and there are made by independently manufacturing. While preparing and forming the flexible OLED display panel, stacking the polarizer and the touch electrode layer and binding by adhesive, such that also increases thickness of the flexible display panel.

While thickness of the flexible display panel is larger, it wills effects affect of bending and curving. Therefore, if needs to provide a curvable, bendable flexible OLED display panel product, it should decrease thickness of every layers and enhances strength of the every layers.

### SUMMARY

A technical problem to be solved by the disclosure is to provide a method of preparing functional film. This disclosure could reduce thickness of the flexible display panel, enhances curving property of the flexible display panel such that easily curving or banding the flexible display panel.

An objective of the disclosure is achieved by following embodiments. In particular, a method of preparing functional film, the functional film used for a flexible display panel, comprising

forming a linear polarizer and a phase difference film by coating liquid crystal on a first side of a substrate, the linear polarizer is located between the substrate and the phase difference film, or the phase difference film is located between the substrate and the linear polarizer;

forming a touch electrode layer on the first side or a second side of the substrate.

In an embodiment, while forming the touch electrode layer on the first side of the substrate, sequentially forming the phase difference film, the linear polarizer and the touch electrode layer on the first side which is far away the substrate; or sequentially forming the touch electrode layer, the phase difference film and the linear polarizer on the first side which is far away the substrate.

In an embodiment, while sequentially forming the phase difference film, the linear polarizer and the touch electrode layer on the first side which is far away the substrate, the method comprising following steps:

forming an organic planar layer on the linear polarizer, and the organic planar layer is located between the touch electrode layer and the linear polarizer;

while sequentially forming the touch electrode layer, the phase difference film and the linear polarizer on the first side which is far away the substrate, the method comprising following steps:

forming an organic planar layer on the touch electrode layer, and the organic planar layer is located between the phase difference film and the touch electrode layer.

In an embodiment, the method of preparing functional film further comprising:

forming an electrode protecting layer on a side of the touch electrode layer which far away the substrate, and thickness of the electrode protecting layer is 1-2 μm, and totally thickness of the touch electrode layer and the organic planar layer are not over 8 μm.

In an embodiment, while forming the touch electrode layer on the second side of the substrate, the method of preparing functional film further comprising:

forming an electrode protecting layer on a side of the touch electrode layer which far away the substrate;

sequentially forming the linear polarizer and the phase difference film on the first side of the substrate which is far away the substrate.

In an embodiment, the phase difference film comprising ½ phase difference film and/or ¼ phase difference film.

In an embodiment, forming a touch electrode layer on the first side or the second side of the substrate, specifically:

forming a conducting film on the first side or the second side of the substrate;

obtaining the touch electrode layer by treating the conducting film by printing process or etching the conducting film.

In an embodiment, thickness of the substrate is 10˜50 μm, totally thickness of the linear polarizer and the phase difference film is 2˜10 μm, thickness of the flexible display panel is 30˜70 μm.

In an embodiment, the method of preparing functional film further comprising:

preparing an alignment film on a side of the phase difference film which for preparing the linear polarizer; or preparing the alignment film on a side of the linear polarizer which for preparing the phase difference film.

In an embodiment, the touch electrode layer is single structure, the substrate is PI layer.

According to another aspect of the disclosure, the disclosure further provides a method of preparing functional film, the functional film used for a flexible display panel, comprising

forming a linear polarizer and a phase difference film by coating liquid crystal on a first side of a substrate, the linear polarizer is located between the substrate and the phase difference film, or the phase difference film is located between the substrate and the linear polarizer;

forming a touch electrode layer on the first side or a second side of the substrate;

the touch electrode layer is single structure, the substrate is PI layer.

In an embodiment, while forming the touch electrode layer on the first side of the substrate, sequentially forming the phase difference film, the linear polarizer and the touch electrode layer on the first side which is far away the substrate; or sequentially forming the touch electrode layer, the phase difference film and the linear polarizer on the first side which is far away the substrate.

In an embodiment, while sequentially forming the phase difference film, the linear polarizer and the touch electrode layer on the first side which is far away the substrate, the method comprising following steps:

forming an organic planar layer on the linear polarizer, and the organic planar layer is located between the touch electrode layer and the linear polarizer;

while sequentially forming the touch electrode layer, the phase difference film and the linear polarizer on the first side which is far away the substrate, the method comprising following steps:

forming an organic planar layer on the touch electrode layer, and the organic planar layer is located between the phase difference film and the touch electrode layer.

In an embodiment, the method of preparing functional film further comprising:

forming an electrode protecting layer on a side of the touch electrode layer which far away the substrate, and thickness of the electrode protecting layer is 1-2 μm, and totally thickness of the touch electrode layer and the organic planar layer are not over 8 μm.

In an embodiment, while forming the touch electrode layer on the second side of the substrate, the method of preparing functional film further comprising:

forming an electrode protecting layer on a side of the touch electrode layer which far away the substrate;

sequentially forming the linear polarizer and the phase difference film on the first side of the substrate which is far away the substrate.

In an embodiment, the phase difference film comprising ½ phase difference film and/or ¼ phase difference film.

In an embodiment, forming a touch electrode layer on the first side or the second side of the substrate, specifically:

forming a conducting film on the first side or the second side of the substrate;

obtaining the touch electrode layer by treating the conducting film by printing process or etching the conducting film.

In an embodiment, thickness of the substrate is 10˜50 μm, totally thickness of the linear polarizer and the phase difference film is 2˜10 μm, thickness of the flexible display panel is 30˜70 μm.

In an embodiment, the method of preparing functional film further comprising:

preparing an alignment film on a side of the phase difference film which for preparing the linear polarizer; or preparing the alignment film on a side of the linear polarizer which for preparing the phase difference film.

In sum, the disclosure according to preparing the linear polarizer and the phase difference film, and the touch electrode layer beside the substrate, which avoids to separately prepare the polarizer and touch electrode layer, and then compositing the polarizer and touch electrode layer together by the adhesive, so that reduces thickness of the functional film. Secondly, the linear polarizer and the phase difference film are preparing by coating liquid crystal, which could using adhesive force between the liquid crystal to adhere together, which avoids to adhere by the adhesive, so that reduces thickness of the functional film. Therefore, the disclosure reduces thickness of the flexible display panel, let the flexible display panel are easily curing, banding, enhances curving property of the flexible display panel, and achieves effect of the curving.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a flow chat diagram of a method of preparing functional film according to an embodiment of the disclosure;

FIG. 2 is a structural schematic view of a functional film according to a first embodiment of the disclosure;

FIG. 3 is a structural schematic view of a functional film according to a second embodiment of the disclosure;

FIG. 4 is a structural schematic view of a functional film according to a third embodiment of the disclosure;

FIG. 5 is a flow chat diagram of a method of preparing functional film according to a fourth embodiment of the disclosure; and;

FIG. 6 is a flow chat diagram of a method of preparing functional film according to a fifth embodiment of the disclosure.

### DETAILED DESCRIPTION OF PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

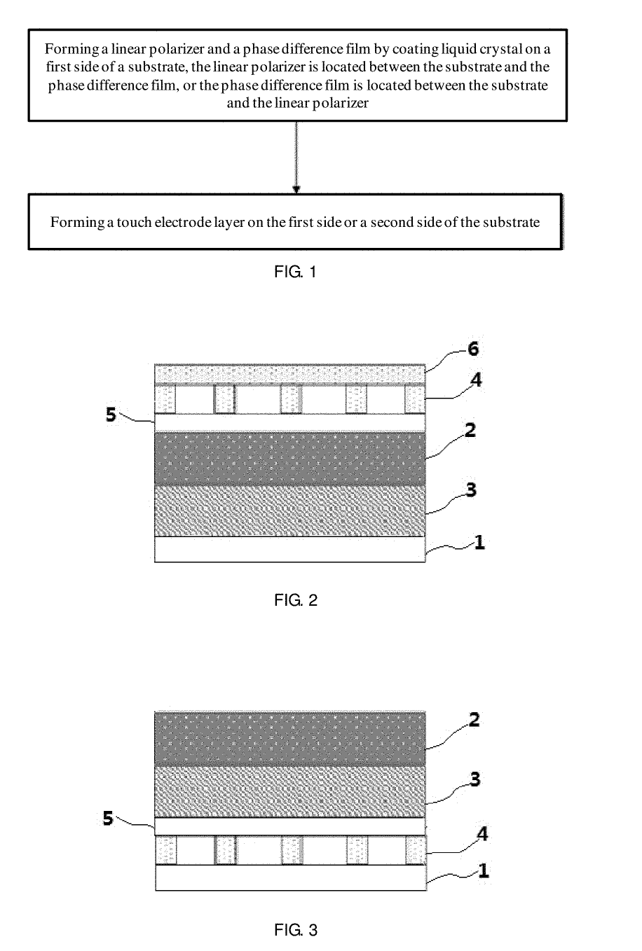

A method of preparing functional film provided by this disclosure, the functional film is used for a flexible display panel. Please refer to FIG. 1, the method comprises following steps.

Forming a linear polarizer and a phase difference film by coating liquid crystal on a first side of a substrate, the linear polarizer is located between the substrate and the phase difference film; or the phase difference film is located between the substrate and the linear polarizer. The linear polarizer and the phase difference film are composed to a polarizer.

Forming a touch electrode layer on the first side or a second side of the substrate. Wherein, the first side and the second side of the substrate are respectively a top side and a bottom side of the substrate; or respectively the bottom side and the top side of the substrate.

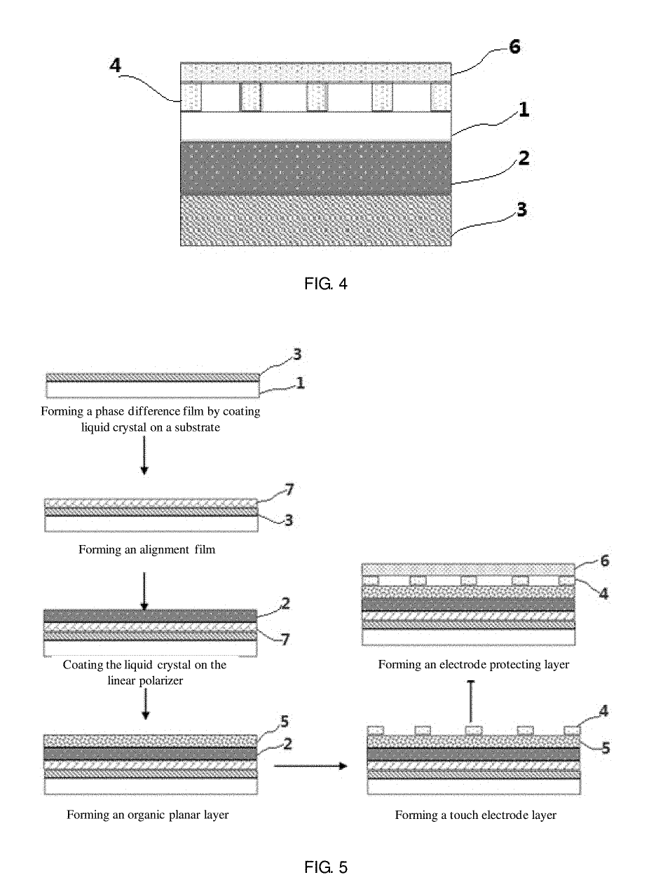

In the first embodiment shows in FIG. 2 and the second embodiment shows in FIG. 3, the linear polarizer 2, the phase difference film 3 and the touch electrode 4 are positioned on same side of the substrate 1. In the fourth embodiment shows in FIG. 4, the linear polarizer 2 and the phase difference film 3, and the touch electrode 4 are respectively positioned beside the substrate 1.

In the method of preparing functional film of this disclosure, coating liquid crystal to form the linear polarizer 2 and the phase difference film 3, and composing the linear polarizer 2 and the phase difference film 3 together by adhesive force between the liquid crystal. Therefore, it does not need adhesive for compositing the linear polarizer 2 and the phase difference film 3. It reduces thickness of polarizer, and also reduces thickness of the flexible display panel.

Furthermore, directly preparing the touch electrode layer 4, the linear polarizer 2 and the phase difference film 3 on the same substrate 1, such that it does not need any gel to be adhesive between the linear polarizer 2 and the phase difference film 3 while compositing the flexible display panel. It reduces thickness of the flexible display panel.

Therefore, the method of preparing functional film provided by this disclosure, it could reduce thickness of the touch display panel and easily curving, banding the touch display panel.

Further, please refer to FIG. 2, while forming the touch electrode layer 4 on the first side of the substrate 1, sequentially forming the phase difference film 3, the linear polarizer 2 and the touch electrode layer 4 on the first side of the substrate 1 which is far away the substrate 1. Or please refer to FIG. 3, sequentially forming the touch electrode layer 4, the phase difference film 3 and the linear polarizer 2 on the first side which is far away the substrate 1.

Further, while sequentially forming the phase difference film 3, the linear polarizer 2 and the touch electrode layer 4 on the first side of the substrate 1 which is far away the substrate 1. The method of preparing functional film further comprising following steps:

forming an organic planar layer 5 on the linear polarizer 2, and the organic planar layer 5 is located between the touch electrode layer 4 and the linear polarizer 2.

While sequentially forming the touch electrode layer 4, the phase difference film 3 and the linear polarizer 2 on the first side which is far away the substrate 1, the method comprising following steps:

forming an organic planar layer 5 on the touch electrode layer 4, and the organic planar layer 5 is located between the phase difference film 3 and the touch electrode layer 4.

Further, the method of preparing functional film further comprising:

Forming an electrode protecting layer 6 on a side of the touch electrode layer 4 which far away the substrate 1, and thickness of the electrode protecting layer 6 is 1-2 μm, and totally thickness of the touch electrode layer 4 and the organic planar layer 5 are not over 8 μm.

Further, while forming the touch electrode layer 4 on the second side of the substrate 1, the method of preparing functional film further comprising:

please refer to FIG. 4, forming an electrode protecting layer 6 on a side of the touch electrode layer 4 which far away the substrate 1;

sequentially forming the linear polarizer 2 and the phase difference film 3 on the first side of the substrate 1 which is far away the substrate 1.

Further, the phase difference film 3 comprising ½ phase difference film (also called ½λ phase difference film or half-wave plate) and/or ¼ phase difference film (also called ¼λ phase difference film or quarter-wave plate), λ is wavelength of the incident light. The half-wave plate used for the phase difference between the ordinary light (o light) and the extraordinary light (e light) is n or odd times while the normal incidence light pass through; the quarter-wave plate used for the phase difference between the ordinary light (o light) and the extraordinary light (e light) is π/2 or odd times while the normal incidence light pass through.

Further, forming the touch electrode layer 4 on the first side or the second side of the substrate, specifically is that:

forming a conducting film 8 on the first side or the second side of the substrate 1;

obtaining the touch electrode layer 4 by treating the conducting film 8 by printing process or etching the conducting film 8.

Further, thickness of the substrate 1 is 10˜50 μm, totally thickness of the linear polarizer 2 and the phase difference film 3 are 2˜10 μm, thickness of the flexible display panel is 30˜70 μm. Further, thickness of the linear polarizer 2 which preparing by coating of the liquid crystal is achieves to 1˜2 μm, but thickness of the polarizer of the existing technology usually more than 5 μm. Therefore, using the method by coating the liquid crystal for preparing the linear polarizer 2 could reduce thickness of polarizer, also reduce thickness of the flexible display panel.

Furthermore, the method of preparing functional film further comprising:

Preparing an alignment film 7 on a side of the phase difference film 3 which for preparing the linear polarizer 2; or preparing the alignment film 7 on a side of the linear polarizer 2 which for preparing the phase difference film 3. Specifically, while preparing the linear polarizer 2 on the substrate 1 and then preparing the phase difference film 3, preparing the alignment film 7 on a side of the linear polarizer 2 which for preparing the phase difference film 3; while preparing the phase difference film 3 on the substrate 1 and then preparing the linear polarizer 2, preparing the alignment film 7 on a side of the phase difference film 3 which for preparing the linear polarizer 2.

Further, the touch electrode layer 4 is single structure; the substrate 1 is PI (polyimide) layer.

Please refer to FIG. 5, in the fourth embodiment, the method of preparing functional film comprising the following steps:

forming a phase difference film 3 by coating liquid crystal on a substrate 1, the phase difference film 3 is ¼ phase difference film;

forming an alignment film 7; material of the alignment film 7 could be PI material, coating the PI material on the phase difference film 3 and processes by the light exposure and baking to form the alignment film 7;

the linear polarizer 2 of liquid crystal coating, which is coating the liquid crystal on the alignment film 7 to form the linear polarizer 2;

forming an organic planar layer 5 on the linear polarizer 2;

forming a touch electrode layer 4 by printing process;

forming an electrode protecting layer 6 on the touch electrode layer 4;

however, this step could be selectively manufactured.

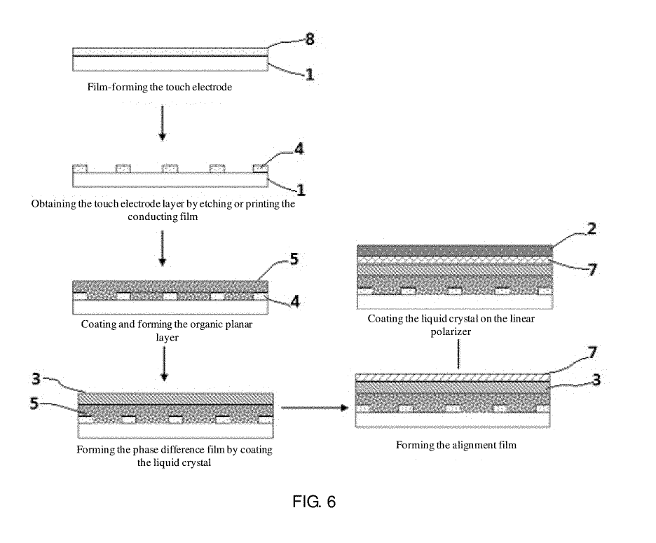

Please refer to FIG. 6, in the fifth embodiment, the method of preparing functional film comprising the following steps:

film-forming the touch electrode, which is forming a conducting film 8 which used for preparing the touch electrode layer 4 on the substrate 1;

obtaining the touch electrode layer 4 by etching or printing the conducting film 8;

coating and forming the organic planar layer 5 on the touch electrode layer 4;

forming the phase difference film 3 by coating the liquid crystal on the organic planar layer 5, the phase difference film 3 could be ¼ phase difference film;

forming the alignment film 7, specifically is coating the liquid crystal on the phase difference film 3 and processes by the light exposure and baking to form the alignment film 7;

the linear polarizer 2 of liquid crystal coating, which is coating the liquid crystal on the alignment film 7 to form the linear polarizer 2.

In sum, the disclosure according to preparing the linear polarizer 2 and the phase difference film 3, and the touch electrode layer 4 beside the substrate 1, which avoids to separately prepare the polarizer and touch electrode layer 4, and then compositing the polarizer and touch electrode layer 4 together by the adhesive, so that reduces thickness of the functional film. Secondly, the linear polarizer 2 and the phase difference film 3 are preparing by coating liquid crystal, which could using adhesive force between the liquid crystal to adhere together, which avoids to adhere by the adhesive, so that reduces thickness of the functional film. Therefore, the linear polarizer 2 and the phase difference film 3 are integrated together in this disclosure, reduces pasting process between films, reduces thickness of the flexible display panel, let the flexible display panel are easily curing, banding, enhances curving property of the flexible display panel, and achieves effect of the curving.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A method of preparing functional film, the functional film used for a flexible display panel, comprising
forming a linear polarizer and a phase difference film by coating liquid crystal on a first side of a substrate, the linear polarizer is located between the substrate and the phase difference film, or the phase difference film is located between the substrate and the linear polarizer;
forming a touch electrode layer on the first side or a second side of the substrate.

2. The method of preparing functional film according to claim 1, wherein while forming the touch electrode layer on the first side of the substrate, sequentially forming the phase difference film, the linear polarizer and the touch electrode layer on the first side which is far away the substrate; or sequentially forming the touch electrode layer, the phase difference film and the linear polarizer on the first side of the substrate which is far away the substrate.

3. The method of preparing functional film according to claim 2, wherein
while sequentially forming the phase difference film, the linear polarizer and the touch electrode layer on the first side which is far away the substrate, the method comprising following steps:
forming an organic planar layer on the linear polarizer, and the organic planar layer is located between the touch electrode layer and the linear polarizer;
while sequentially forming the touch electrode layer, the phase difference film and the linear polarizer on the first side which is far away the substrate, the method comprising following steps:
forming an organic planar layer on the touch electrode layer, and the organic planar layer is located between the phase difference film and the touch electrode layer.

4. The method of preparing functional film according to claim 3, wherein the method of preparing functional film further comprising:
forming an electrode protecting layer on a side of the touch electrode layer which far away the substrate, and thickness of the electrode protecting layer is 1-2 μm, and totally thickness of the touch electrode layer and the organic planar layer are not over 8 μm.

5. The method of preparing functional film according to claim 1, wherein while forming the touch electrode layer on the second side of the substrate, the method of preparing functional film further comprising:
forming an electrode protecting layer on a side of the touch electrode layer which far away the substrate;
sequentially forming the linear polarizer and the phase difference film on the first side of the substrate which is far away the substrate.

6. The method of preparing functional film according to claim 1, wherein the phase difference film comprising ½ phase difference film and/or ¼ phase difference film.

7. The method of preparing functional film according to claim 1, wherein forming the touch electrode layer on the first side or the second side of the substrate, specifically:
forming a conducting film on the first side or the second side of the substrate;
obtaining the touch electrode layer by treating the conducting film by printing process or etching the conducting film.

8. The method of preparing functional film according to claim 1, wherein thickness of the substrate is 10˜50 μm, totally thickness of the linear polarizer and the phase difference film is 2˜10 μm, thickness of the flexible display panel is 30˜70 μm.

9. The method of preparing functional film according to claim 1, wherein the method of preparing functional film further comprising:
preparing an alignment film on a side of the phase difference film which for preparing the linear polarizer; or preparing the alignment film on a side of the linear polarizer which for preparing the phase difference film.

10. The method of preparing functional film according to claim 1, wherein the touch electrode layer is single structure, the substrate is PI layer.

11. A method of preparing functional film, the functional film used for a flexible display panel, comprising
forming a linear polarizer and a phase difference film by coating liquid crystal on a first side of a substrate, the linear polarizer is located between the substrate and the phase difference film, or the phase difference film is located between the substrate and the linear polarizer;
forming a touch electrode layer on the first side or a second side of the substrate;
the touch electrode layer is single structure, the substrate is PI layer.

12. The method of preparing functional film according to claim 11, wherein while forming the touch electrode layer on the first side of the substrate, sequentially forming the phase difference film, the linear polarizer and the touch electrode layer on the first side which is far away the substrate; or sequentially forming the touch electrode layer, the phase difference film and the linear polarizer on the first side which is far away the substrate.

13. The method of preparing functional film according to claim 12, wherein
while sequentially forming the phase difference film, the linear polarizer and the touch electrode layer on the first side which is far away the substrate, the method comprising following steps:
forming an organic planar layer on the linear polarizer, and the organic planar layer is located between the touch electrode layer and the linear polarizer;
while sequentially forming the touch electrode layer, the phase difference film and the linear polarizer on the first side which is far away the substrate, the method comprising following steps:
forming an organic planar layer on the touch electrode layer, and the organic planar layer is located between the phase difference film and the touch electrode layer.

14. The method of preparing functional film according to claim 13, wherein the method of preparing functional film further comprising:
forming an electrode protecting layer on a side of the touch electrode layer which far away the substrate, and thickness of the electrode protecting layer is 1-2 μm, and totally thickness of the touch electrode layer and the organic planar layer are not over 8 μm.

15. The method of preparing functional film according to claim 11, wherein while forming the touch electrode layer on the second side of the substrate, the method of preparing functional film further comprising:
forming an electrode protecting layer on a side of the touch electrode layer which far away the substrate;
sequentially forming the linear polarizer and the phase difference film on the first side of the substrate which is far away the substrate.

16. The method of preparing functional film according to claim 11, wherein the phase difference film comprising ½ phase difference film and/or ¼ phase difference film.

17. The method of preparing functional film according to claim 11, wherein forming the touch electrode layer on the first side or the second side of the substrate, specifically:
forming a conducting film on the first side or the second side of the substrate;
obtaining the touch electrode layer by treating the conducting film by printing process or etching the conducting film.

18. The method of preparing functional film according to claim 11, wherein thickness of the substrate is 10˜50 μm, totally thickness of the linear polarizer and the phase difference film is 2˜10 μm, thickness of the flexible display panel is 30˜70 μm.

19. The method of preparing functional film according to claim 11, wherein the method of preparing functional film further comprising:
preparing an alignment film on a side of the phase difference film which for preparing the linear polarizer; or preparing the alignment film on a side of the linear polarizer which for preparing the phase difference film.
